(19) United States
(12) Patent Application Publication
(10) Pub. No.: US 2026/0006714 A1
(43) Pub. Date: Jan. 1, 2026

(54) PRINTED CIRCUIT BOARD AND MANUFACTURING METHOD FOR THE SAME

(71) Applicant: SAMSUNG ELECTRO-MECHANICS CO., LTD., Suwon-si (KR)

(72) Inventors: Tae Hong MIN, Suwon-si (KR); Jong Eun PARK, Suwon-si (KR)

(73) Assignee: SAMSUNG ELECTRO-MECHANICS CO., LTD., Suwon-si (KR)

(21) Appl. No.: 19/213,240

(22) Filed: May 20, 2025

(30) Foreign Application Priority Data
Jul. 1, 2024 (KR) 10-2024-0086013
Feb. 4, 2025 (KR) 10-2025-0013970

(51) Int. Cl. H05K 1/02; H05K 1/03; H05K 1/11; H05K 1/18

(52) U.S. Cl. CPC H05K 1/0271; H05K 1/0306; H05K 1/113; H05K 1/181; H05K 1/185; H05K 2201/0209; H05K 2201/0275; H05K 2201/068; H05K 2201/09527; H05K 2201/096; H05K 2201/09609; H05K 2201/09827; H05K 2201/10522; H05K 2201/2018

(57) ABSTRACT

The present disclosure relates to a printed circuit board including: a frame having a through-portion; a glass layer at least partially disposed within the through-portion; a first insulating material filling at least a portion of a space between the frame and the glass layer; a second insulating material disposed on upper sides of the frame and the glass layer; and a third insulating material disposed on lower sides of the frame and the glass layer, and the first insulating material includes a material different from the second and third insulating materials.

### CROSS-REFERENCE TO RELATED APPLICATION(S)

This application claims the benefit of priority to Korean Patent Application Nos. 10-2024-0086013 and 10-2025-0013970 filed on Jul. 1, 2024, and Feb. 4, 2025, in the Korean Intellectual Property Office, the disclosures of which are incorporated herein by reference in their entirety.

### TECHNICAL FIELD

The present disclosure relates to a printed circuit board and a manufacturing method for the same.

### BACKGROUND

Efforts to improve the performance of electronic products are moving beyond semiconductors to packaging, and products utilizing glass substrates, such as large-area substrates for servers, are attracting attention as next-generation technologies. Glass substrates may have advantages over organic substrates formed of epoxy materials in terms of heat dissipation, warpage control, large-area, and microcircuit implementation. However, glass substrates may be subject to fracturing due to the occurrence and propagation of cracks during processing or transportation. In this case, glass particles may enter the product through various paths such as processing equipment or chemicals, which may lead to product defects. Therefore, it may be necessary to solve the problem of cracks or fractures of glass.

### SUMMARY

An aspect of the present disclosure is to provide a printed circuit board including a glass layer and capable of effectively preventing cracks or fractures of glass and a manufacturing method for the same.

In one solution proposed by the present disclosure, at least a portion of a glass layer is disposed in a frame having a through-portion, and in this case, a first insulating material filling at least a portion of a space between a frame and a glass layer and second and third insulating materials disposed on each of an upper side and a lower side of the frame and the glass layer are formed of different materials.

For example, a printed circuit board according to an embodiment may include: a frame having a through-portion; a glass layer at least partially disposed within the through-portion; a first insulating material filling at least a portion of a space between the frame and the glass layer; a second insulating material disposed on upper sides of the frame and the glass layer; and a third insulating material disposed on lower sides of the frame and the glass layer, the first insulating material may include a material different from the second and third insulating materials.

For example, a printed circuit board according to an embodiment may include: a glass layer; a frame spaced apart from the glass layer and surrounding a side surface of the glass layer; a first insulating material filling at least a portion of a space between the glass layer and the frame; a second insulating material covering at least a portion of each of an upper surface of the glass layer, an upper surface of the frame, and an upper surface of the first insulating material; and a third insulating material covering at least a portion of each of a lower surface of the glass layer, a lower surface of the frame, and a lower surface of the first insulating material, and the first and second insulating materials may have boundaries physically distinct from each other, and the first and third insulating materials may have boundaries physically distinct from each other.

For example, a method for manufacturing a printed circuit board may include: preparing a frame having a through-portion; disposing at least a portion of a glass layer within the through-portion; filling at least a portion of a space between the frame and the glass layer with a first insulating material; forming a second insulating material including a material different from the first insulating material, on upper sides of each of the frame, the glass layer and the first insulating material; and forming a third insulating material including a material different from the first insulating material, on lower sides of each of the frame, the glass layer and the first insulating material.

One effect of the present disclosure is to provide a printed circuit board including a glass layer and capable of effectively preventing cracks or fractures of glass and a manufacturing method for the same.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a schematic cut plan view taken along line A-A of the printed circuit board of FIG. 2;

FIG. 4 schematically illustrates a direction of various stresses generated in a frame, a glass layer, and first to third insulating materials of the printed circuit board of FIG. 2;

FIGS. 5A to 5G are process diagrams schematically illustrating an example of manufacturing the printed circuit board of FIG. 2;

FIGS. 6A and 6B are process diagrams schematically illustrating an example of disposing a plurality of glass layers on a frame having a plurality of through-portions;

FIG. 7 is a cross-sectional view schematically illustrating another example of a printed circuit board;

FIG. 8 is a cross-sectional view schematically illustrating another example of a printed circuit board;

FIG. 9 is a cross-sectional view schematically illustrating another example of a printed circuit board; and

FIG. 10 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clearer description.

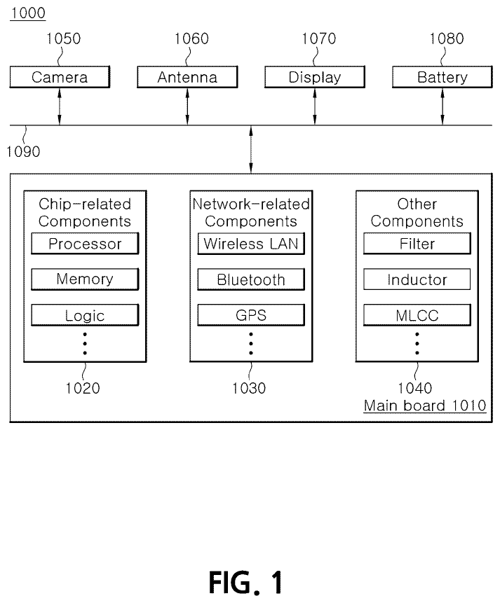

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, an encryption processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. Additionally, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component, and a server. However, the electronic device 1000 is not limited thereto, and may be any other electronic device that processes data in addition thereto.

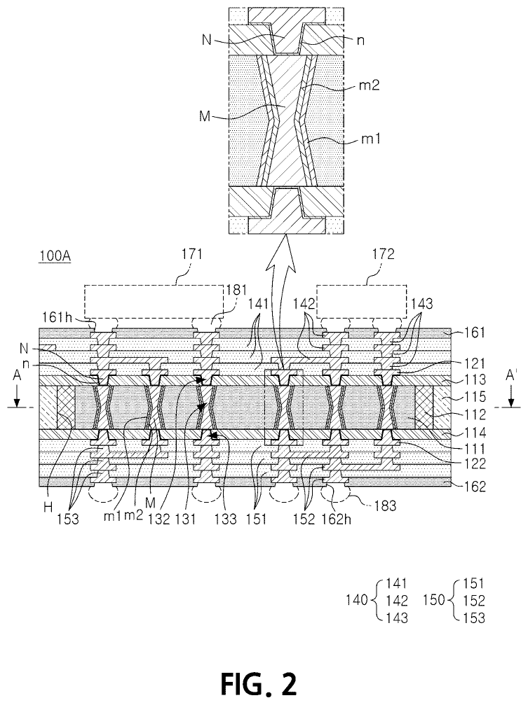

FIG. 2 is a cross-sectional view schematically illustrating an example of a printed circuit board.

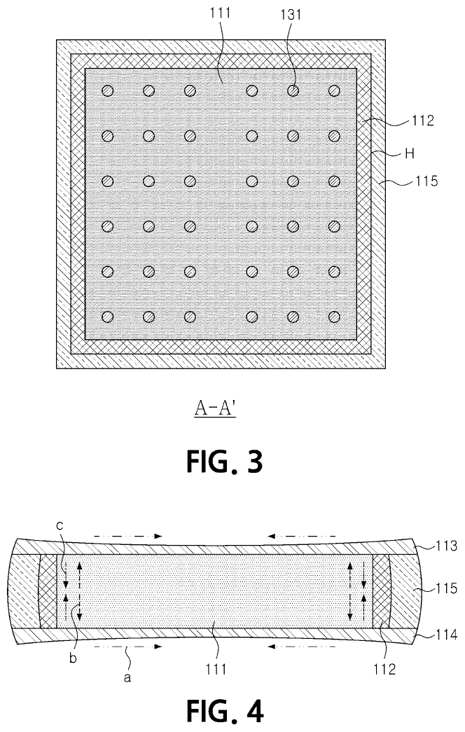

FIG. 3 is a schematic cut plan view taken along line A-A of the printed circuit board of FIG. 2.

FIG. 4 schematically illustrates a direction of various stresses generated in a frame, a glass layer, and first to third insulating materials of the printed circuit board of FIG. 2.

Referring to the drawings, a printed circuit board 100A according to an example embodiment may include a frame 115 having a through-portion H, a glass layer 111 at least partially disposed within the through-portion H, a first insulating material 112 filling at least a portion of a space between the frame 115 and the glass layer 111, a second insulating material 113 disposed on upper sides of the frame 115 and the glass layer 111, and a third insulating material 114 disposed on lower sides of the frame 115 and the glass layer 111. The second insulating material 113 may cover at least a portion of each of an upper surface of the frame 115, an upper surface of the glass layer 111, and an upper surface of the first insulating material 112, and may, for example, be in contact with at least a portion of each thereof. The third insulating material 114 may cover at least a portion of a lower surface of the frame 115, a lower surface of the glass layer 111, and a lower surface of the first insulating material 112, and may, for example, be in contact with at least a portion of each thereof.

As illustrated in FIG. 4, when the second and third insulating materials 113 and 114 are contracted (a) during a process, tensile stress (b) may occur in the glass layer 111. In this case, cracks or fractures may occur at corners of the glass layer 111. To resolve the cracks or fractures, compressive stress (c) may be required through the frame 115 and/or the first insulating material 112. In this case, cracks or fractures in the glass layer 111 may be effectively prevented. From this perspective, the first insulating material 112 may include a different material from the second and third insulating materials 113 and 114. Here, the different materials may denote that the composition, electrical properties (e.g., permittivity and dielectric strength), thermal properties (e.g., thermal conductivity and coefficient of thermal expansion), and mechanical properties (e.g., strength and flexibility) of the materials are different. For example, the basic components of the materials used in each insulating material may be different from each other, or even if the same components are included therein, mixing ratios, additive types and contents, material processing methods (e.g., curing conditions, particle distribution, mixing homogeneity) thereof may be different. Due to these differences, each insulating material may exhibit different characteristics in terms of electrical performance, thermal stability, environmental durability, physical strength, or manufacturing process suitability.

For example, coefficients of thermal expansion of each of the second and third insulating materials 113 and 114 may be smaller than a coefficient of thermal expansion of the glass layer 111. In this case, the tensile stress (b) described above may be minimized. Additionally, coefficients of thermal expansion of each of the frame 115 and the first insulating material 112 may be greater than the coefficient of thermal expansion of the glass layer 111. In this case, the compressive stress (c) described above may be effectively generated. Accordingly, cracks or fractures in the glass layer 111 may be effectively prevented. Here, the coefficient of thermal expansion (CTE) may be a physical characteristic indicating the degree to which a material is expanded or contracted according to a temperature change. This coefficient of thermal expansion may be measured by preparing a number of samples by separating a measurement target (e.g., each insulating material, each frame, and/or each glass layer) by physical cutting or chemical treatment in a final product, and then using a thermomechanical analyzer (TMA), X-ray diffraction analysis (XRD), an interferometer, digital image analysis, or the like. The coefficients of thermal expansion may be compared by unifying measurement conditions such as a stress state, an axial direction, a thickness, and a temperature range, and if the conditions are different, the data may be normalized or divided by a specific reference value to evaluate a relative size relationship.

As a more specific example, the frame 115 may have a coefficient of thermal expansion of about 5 ppm/° C. to 30 ppm/° C., the glass layer 111 may have a coefficient of thermal expansion of about 3 ppm/° C. to 10 ppm/° C., the first insulating material 112 may have a coefficient of thermal expansion of about 10 ppm/° C. to 20 ppm/° C., and the second and third insulating materials 113 and 114 may have a coefficient of thermal expansion of about 2 ppm/° C. to 10 ppm/° C., respectively. For example, the frame 115 may have a coefficient of thermal expansion of about 30 ppm/° C., the glass layer 111 may have a coefficient of thermal expansion of about 7 ppm/° C., the first insulating material 112 may have a coefficient of thermal expansion of about 15 ppm/° C., and each of the second and third insulating materials 113 and 114 may have a coefficient of thermal expansion of about 5 ppm/° C. As another example, the frame 115 may have a coefficient of thermal expansion of about 30 ppm/° C., the glass layer 111 may have a coefficient of thermal expansion of about 4 ppm/° C., the first insulating material 112 may have a coefficient of thermal expansion of about 15 ppm/° C., and each of the second and third insulating materials 113 and 114 may have a coefficient of thermal expansion of about 3 ppm/° C. These coefficients of thermal expansion may be measured in X-/Y-directions or a Z-direction under temperature conditions of 25° C. to 150° C. or 150° C. to 240° C. below a glass transition temperature.

Additionally, each of the first to third insulating materials 112, 113 and 114 may include an insulating resin and an inorganic filler, and in this case, a content ratio of the inorganic filler included in the first insulating material 112 may be smaller than a content ratio of the inorganic filler included in each of the second and third insulating materials 113 and 114. For example, in the same cut cross-section, an area ratio of the inorganic filler included in the first insulating material 112 may be smaller than an area ratio of the inorganic filler included in the second insulating material 113 and an area ratio of the inorganic filler included in the third insulating material 114, respectively. In this case, the coefficient of thermal expansion of the first insulating material 112 may be greater than the coefficients of thermal expansion of each of the second and third insulating materials 113 and 114. Accordingly, the above-described compressive stress (c) may be effectively generated through the first insulating material 112, and as a result, cracks or fractures in the glass layer 111 may be effectively prevented. Here, the area ratio may refer to a ratio of an area occupied by the inorganic filler per unit area, and may be measured by obtaining an image of a cross-section cut in an arbitrary direction using a scanning electron microscope or an optical microscope, and then distinguishing and calculating the areas of the filler and the insulating resin using image analysis software. For example, the inorganic filler may be identified based on the contrast, a color difference, or a unique shape of the inorganic filler during an analysis process, and areas of the inorganic filler within a specific region may be added and converted into a ratio to the total cross-sectional area. Accordingly, inorganic filler area ratios of each insulating material may be compared. In the case in which the area ratios are almost similar, values at five arbitrary cut cross-sections may be measured and then average values thereof may be compared.

Additionally, the second and third insulating materials 113 and 114 may include glass fiber (glass fiber glass cloth, or glass fabric) as a core material, while the first insulating material 112 may not include a core material such as glass fiber. In this case, the first insulating material 112 may be formed more easily in the space between the frame 115 and the glass layer 111, and process warpage may be controlled more effectively through the second and third insulating materials 113 and 114. Additionally, a magnitude relationship between the content ratios and/or the area ratios of the inorganic fillers of each of the first to third insulating materials 112, 113 and 114 may be more effectively satisfied. Additionally, the magnitude relationship between the coefficients of thermal expansion of each of the first to third insulating materials 112, 113 and 114 may be more effectively satisfied. Accordingly, cracks or fractures of the glass layer 111 may be effectively prevented.

Additionally, the frame 115 may include a material having excellent rigidity, and may include, for example, a copper-clad laminate (CCL) or an unclad copper-clad laminate (Unclad CCL). In this case, as described below, the process may be performed on a panel level through the frame 115, and therefore, this may be advantageous for process warpage control. Additionally, by allowing the frame 115 to remain in a final substrate unit after a singulation process, this may be structurally advantageous for warpage control. Additionally, by utilizing a material having a coefficient of thermal expansion greater than that of the glass layer 111 as the material of the frame 115, the compressive stress (c) described above may be generated, thereby more effectively preventing cracks or fractures in the glass layer 111 during the process.

As a more specific example, the frame 115 may include an epoxy resin, a silica filler and a silica fabric, and the first insulating material 112 may include an epoxy resin and a silica filler, and each of the second and third insulating materials 113 and 114 may include an epoxy resin, a silica filler and a silica fabric. Additionally, the glass layer 111 may preferably include SiO₂, B₂O₃, Al₂O₃, Na₂O, K₂O and/or Cao, in order to satisfy the above-described coefficient of thermal expansion relationship.

The first to third insulating materials 112, 113 and 114 may be respective insulating layers having boundaries distinct from each other. For example, the first insulating material 112 may include a different material from the second and third insulating materials 113 and 114, and thus boundaries thereof may be distinct from each other. Specifically, the first and second insulating materials 112 and 113 may have physical boundaries with each other, and the first and third insulating materials 112 and 114 may have physical boundaries with each other. In this case, cracks or fractures of the glass layer 111 may be effectively prevented. In this case, the upper surface of the first insulating material 112 may be substantially coplanar with the upper surface of the glass layer 111, and the lower surface of insulating material 112 may be substantially coplanar with the lower surface of the glass layer 111. In this structure, by generating the compressive stress (c) described above in the first insulating material 112, cracks or fractures of the glass layer 111 may be more effectively prevented during the process. Additionally, undulation may be prevented from occurring in the second and third insulating materials 113 and 114. Accordingly, the flatness may be increased, which may be more advantageous for implementing microcircuits.

Referring to the drawing, a printed circuit board 100A according to an example embodiment may further include a through-via 131 penetrating through a glass layer 111, a first connection via 132 penetrating through a second insulating material 113 and connected to an upper side of the through-via 131, a second connection via 133 penetrating through a third insulating material 114 and connected to a lower side of the through-via 131, a first interconnection layer 121 which is disposed on an upper surface of the second insulating material 113 and in which at least a portion thereof is connected to the first connection via 132, and/or a second interconnection layer 122 which is disposed on a lower surface of the third insulating material 114 and in which at least a portion thereof is connected to the second connection via 133. Accordingly, various interconnection designs may be possible. Additionally, various electrical connection paths may be provided. The first and second connection vias 132 and 133 may be in direct contact with an upper surface and a lower surface of the through-via 131, respectively, and in this case, a thinner structure may be achieved.

The through-via 131 may be a Through-Glass Via (TGV). The through-via 131 may include first seed layers m1 and m2 having a multilayer structure formed by sputtering. For example, the through-via 131 may include first seed layers m1 and m2 disposed on a wall surface of a through-hole penetrating through the glass layer 111 and a first metal layer M disposed on the first seed layers m1 and m2 to fill at least a portion of the through-hole, and in this case, the first seed layers m1 and m2 may include a first layer m1 including sputtered titanium, and a second layer m2 including sputtered copper, and the first metal layer M may include electrolytic copper. Each of the through-hole and the through-via 131 formed therein may have an hourglass shape in a cross-section, but the present disclosure is not limited thereto. An upper surface and a lower surface of the through-via 131 may be substantially coplanar with the upper surface and the lower surface of the glass layer 111, respectively, but the present disclosure is not limited thereto, and the upper surface and the lower surface of the through-via 131 may be recessed more inwardly than the upper surface and the lower surface of the glass layer 111. A recessed space on the upper surface and lower surface of the through-via 131 may be filled at least partially with the second and third insulating materials 113 and 114, respectively.

Additionally, each of the first and second connection vias 132 and 133 may be Blind Via (BV). The first connection via 132 may include a second seed layer n formed by electroless plating. For example, the second connection via 133 may include a second seed layer n disposed on a wall surface of a first via hole penetrating through the second insulating material 113 and exposing an upper surface of the through-via 131, and a second metal layer N disposed on the second seed layer n and filling at least a portion of the first via hole, and in this case, the second seed layer n may include chemical copper, and the second metal layer N may include electrolytic copper. In substantially the same manner, the second connection via 133 may include a third seed layer disposed on a wall surface of the second via hole penetrating through the third insulating material 114 and exposing a lower surface of the through-via 131, and a third metal layer disposed on the third seed layer and filling at least a portion of the second via hole, in which case the third seed layer may include chemical copper, and the third metal layer may include electrolytic copper. The first and second connection vias 132 and 133 may have substantially tapered shapes in opposite directions in a cross-section. For example, the first via hole and the first connection via 132 formed therein may have a substantially tapered shape in which a width of an upper end thereof is greater than a width of a lower end thereof in a cross-section, and the second via hole and the second connection via 133 formed therein may have a substantially tapered shape in which a width of a lower end thereof is greater than a width of an upper end thereof in a cross-section, but the present disclosure is not limited thereto.

Referring to the drawing, the printed circuit board 100A according to an example embodiment may further include a first build-up layer 140 disposed on an upper side of the second insulating material 113 and a second build-up layer 150 disposed on a lower side of the third insulating material 114. The first build-up layer 140 may include a plurality of first build-up insulating layers 141 stacked on an upper surface of the second insulating material 113, a plurality of first build-up interconnection layers 142 respectively disposed on or within upper surfaces of the plurality of first build-up insulating layers 141, and a plurality of first build-up via layers 143 respectively disposed within the plurality of first build-up insulating layers 141. The second build-up layer 150 may further include a plurality of second build-up insulating layers 151 stacked on the lower surface of the third insulating material 114, a plurality of second build-up s 152 respectively disposed on or within a lower surface of the plurality of second build-up insulating layers 151, and a plurality of second build-up via layers 153 respectively disposed within the plurality of second build-up insulating layers 151. An electrical connection path from an uppermost side to a lowermost side of a substrate may be provided through the plurality of first and second build-up interconnection layers 142 and 152 and the plurality of first and second build-up via layers 143 and 153. For example, a printed circuit board 100A according to an example embodiment may include a glass layer 111 and first to third insulating materials 112, 113 and 114 and a frame 115 as a core layer, and may have a multilayer substrate structure in which first and second build-up layers 140 and 150 are built up on both sides of the core layer. Accordingly, the printed circuit board 100A may be easily applied to a large-area package substrate.

A first solder resist layer 161 having a plurality of first openings 161h respectively exposing at least a portion of a first build-up interconnection layer 142 on an uppermost side may be disposed on an upper surface of a first build-up insulating layer 141 on an uppermost side, and a second solder resist layer 162 having a plurality of second openings 162h respectively exposing at least a portion of a second build-up interconnection layer 152 on a lowermost side may be disposed on a lower surface of a second build-up insulating layer 151 on a lowermost side. A plurality of first electrical connection metals 181 respectively connected to at least the exposed portion of the first build-up interconnection layer 142 on the uppermost side may be disposed on the plurality of first openings 161h, and a plurality of second electrical connection metals 183 respectively connected to at least the exposed portion of the second build-up interconnection layer 152 on the lowermost side may be disposed on the plurality of second openings 162h. First and second electronic components 171 and 172 respectively connected to the plurality of first electrical connection metals 181 may be mounted on an upper surface of the first solder resist layer 161. For example, a printed circuit board 100A according to an example embodiment may have a package structure in which electronic components are mounted on a package substrate.

Hereinafter, components of the printed circuit board 100A will be described in more detail with reference to the drawings.

The glass layer 111 may include glass, which is an amorphous solid. The glass may include, for example, pure silicon dioxide (about 100% SiO₂), soda lime glass, borosilicate glass, and aluminosilicate glass. However, the present disclosure is not limited thereto, and alternative glass materials, for example, fluorine glass, phosphate glass, chalcogen glass, or the like, may also be used as materials. Additionally, other additives may be further included to form a glass having specific physical properties. Such additives may include calcium carbonate (e.g., lime) and sodium carbonate (e.g., soda), as well as magnesium, calcium, manganese, aluminum, lead, boron, iron, chromium, potassium, sulfur and antimony, and carbonates and/or oxides of these elements and other elements. The glass layer 111 may be a layer distinct from organic insulating materials including glass fiber (Glass Fiber, Glass Cloth or Glass Fabric), such as Copper Clad Laminate (CCL), and Prepreg (PPG). For example, the glass layer 111 may include a glass panel that may be enlarged, for example, a glass plate.

Each of the first to third insulating materials 112, 113 and 114 may include an organic insulating material. The organic insulating material may include a thermosetting resin such as an epoxy resin, a thermoplastic resin such as a polyimide, or a material including an inorganic filler, an organic filler, and/or glass fiber (Glass Fiber, Glass Cloth or Glass Fabric) together with these resins. For example, the first insulating material 112 may include an adhesive sheet such as a Bonding Sheet (BS), a filling agent, and the like, but the present disclosure is not limited thereto. Additionally, the second and third insulating materials 113 and 114 may include non-photosensitive insulating materials such as an Ajinomoto Build-up Film (ABF), Prepreg (PPG), or photosensitive insulating materials such as Photoimageable Dielectric (PID), but the present disclosure is not limited thereto.

The frame 115 may include an organic insulating material. The organic insulating material may include a thermosetting resin such as an epoxy resin, a thermoplastic resin such as a polyimide, or a material including an inorganic filler, an organic filler, and/or glass fiber (Glass Fiber, Glass Cloth or Glass Fabric) together with these resins. For example, the organic insulating material may be Copper Clad Laminate (CCL), Unclad CCL, or the like, but the present disclosure is not limited thereto. If necessary, in addition to the organic insulating material, other materials such as ceramic or metal may be used as the material of the frame 115, and in this case, the material may be selected in consideration of the coefficient of thermal expansion relationship. The through-portion H may penetrate between the upper surface and the lower surface of the frame 115. The frame 115 may be spaced apart from the glass layer 111 and may surround a side surface of the glass layer 111. The upper surface and the lower surface of the frame 115 may be substantially coplanar with an upper surface and a lower surface of the glass layer 111, respectively, and also, the upper surface and the lower surface of the frame 115 may be substantially coplanar with the upper surface and the lower surface of the first insulating material 112, respectively. In the case in which the frame 115 includes copper foil or the like, the upper surface and the lower surface of the frame 115 may be determined by considering the copper foil.

Each of the first and second interconnection layers 121 and 122 may include a metal. The metal may include copper (Cu), aluminum (Al), silver (Ag), tin (Sn), gold (Au), nickel (Ni), lead (Pb), titanium (Ti), and/or alloys thereof. The first and second interconnection layers 121 and 122 may perform various functions according to the design. For example, the first and second interconnection layers 121 and 122 may include a signal pattern, a power pattern, and a ground pattern. These patterns may have various shapes, such as a line, a plane, a pad, and the like. The first and second interconnection layers 121 and 122 may include an electroless plating layer (or chemical copper) and an electrolytic plating layer (or electrolytic copper).

The through-via 131 may include a metal. The metal may include copper (Cu), aluminum (Al), silver (Ag), tin (Sn), gold (Au), nickel (Ni), lead (Pb), titanium (Ti), and/or alloys thereof. The through-via 131 may perform various functions according to the design. For example, the through-via 131 may include a ground via, a power via, and a signal via. The through-via 131 may have a substantially circular or elliptical shape in a plane, and may have a substantially hourglass shape in a cross-section, but the present disclosure is not limited thereto. The through-via 131 may include a sputtered layer (or a plurality of sputtered metals) and an electrolytic plating layer (or electrolytic copper). The through-via 131 may be provided in plural.

Each of the first and second connection vias 132 and 133 may include a metal. The metal may include copper (Cu), aluminum (Al), silver (Ag), tin (Sn), gold (Au), nickel (Ni), lead (Pb), titanium (Ti), and/or alloys thereof. Each of the first and second connection vias 132 and 133 may include a filled via filling the via hole, but may also include a conformal via disposed along a wall surface of the via hole. The first and second connection vias 132 and 133 may perform various functions depending on the design. For example, the first and second connection vias 132 and 133 may include a ground via, a power via, and a signal via. The first and second connection vias 132 and 133 may have shapes substantially tapered in opposite directions in the cross-section, but the present disclosure is not limited thereto. Each of the first and second connection vias 132 and 133 may include an electroless plating layer (or chemical copper) and an electrolytic plating layer (or electrolytic copper). Each of the first and second connection vias 132 and 133 may be provided in plural.

Each of the plurality of first and second build-up insulating layers 141 and 151 may include an organic insulating material. The organic insulating material may include a thermosetting resin such as an epoxy resin, a thermoplastic resin such as a polyimide, or a material including an inorganic filler, an organic filler, and/or glass fiber (Glass Fiber, Glass Cloth or Glass Fabric) together with these resins. For example, the organic insulating material may be a non-photosensitive insulating material such as an Ajinomoto Build-up Film (ABF) or Prepreg (PPG), but the present disclosure is not limited thereto, and other polymeric materials may be used as the organic insulating material. Additionally, the organic insulating material may be a photosensitive insulating material such as Photoimageable Dielectric (PID). The plurality of first and second build-up insulating layers 141 and 151 may include substantially the same organic insulating material, but the present disclosure is not limited thereto. The plurality of first and second build-up insulating layers 141 and 151 may have the same number of layers, but the present disclosure is not limited thereto. Each of the plurality of first and second build-up insulation layers 141 and 151 may be composed of one or more layers as needed.

Each of the plurality of first and second build-up interconnection layers 142 and 152 may include a metal. The metal may include copper (Cu), aluminum (Al), silver (Ag), tin (Sn), gold (Au), nickel (Ni), lead (Pb), titanium (Ti), and/or alloys thereof. Each of the plurality of first and second build-up interconnection layers 142 and 152 may perform various functions according to the design. For example, the plurality of first and second build-up interconnection layers 142 and 152 may include a signal pattern, a power pattern, and a ground pattern. Each of the patterns may have various shapes such as a line, a plane, a pad. Each of the plurality of first and second build-up interconnection layers 142 and 152 may include an electroless plating layer (or chemical copper) and an electrolytic plating layer (or electrolytic copper). The plurality of first and second build-up interconnection layers 142 and 152 may have the same number of layers, but the present disclosure is not limited thereto. Each of the plurality of first and second build-up interconnection layers 142 and 152 may be composed of one or more layers as needed.

Each of the plurality of first and second build-up via layers 143 and 153 may include a metal. The metal may include copper (Cu), aluminum (Al), silver (Ag), tin (Sn), gold (Au), nickel (Ni), lead (Pb), titanium (Ti), and/or alloys thereof. Each of the one or more first and second build-up via layers 143 and 153 may include a filled via filling a via hole, but may also include a conformal via disposed along a wall surface of the via hole. Each of the plurality of first and second build-up via layers 143 and 153 may perform various functions according to the design. For example, the plurality of first and second build-up via layers 143 and 153 may include a ground via, a power via, and a signal via. The plurality of first and second build-up via layers 143 and 153 may have a shape substantially tapered in an opposite direction in a cross-section. Each of the plurality of first and second build-up via layers 143 and 153 may include an electroless plating layer (or chemical copper) and an electrolytic plating layer (or electrolytic copper). The plurality of first and second build-up via layers 143 and 153 may have the same number of layers, but the present disclosure is not limited thereto. Each of the plurality of first and second build-up via layers 143 and 153 may be composed of one or more layers as needed.

The first and second solder resist layers 161 and 162 may include a liquid or film type solder resist, but the present disclosure is not limited thereto, and other types of insulating materials such as ABF may be used. A surface treatment layer and/or a metal bump may be formed on respective patterns exposed by the plurality of first and second openings 161h and 162h, as needed. Each pattern exposed by the plurality of first and second openings 161h and 162h may be in the form of Solder Mask Defined (SMD) and/or Non-Solder Mask Defined (NSMD), but the present disclosure is not limited thereto. Each of the first and second openings 161h and 162h may be provided in plural.

The plurality of first and second electrical connection metals 181 and 183 may be formed of a low-melting point metal, for example, solder such as tin (Sn)-aluminum (Al)-copper (Cu), but this is only an example, and the material is not particularly limited thereto. The plurality of first and second electrical connection metals 181 and 183 may be balls, pins, or the like. Each of the plurality of first and second electrical connection metals 181 and 183 may be formed of a multilayer or a single layer. When the plurality of first and second electrical connection metals 181 and 183 are formed of multiple layers, they may include a copper pillar and a solder, and when the plurality of first and second electrical connection metals 181 and 183 are formed of a single layer, they may include tin-silver solder, but the present disclosure is not limited thereto. The plurality of first electrical connection metals 181 may be used for mounting the first and second electronic components 171 and 172, and the plurality of second electrical connection metals 183 may be used for mounting a printed circuit board 100A according to an example on another substrate such as a main board.

Each of the first and second electronic components 171 and 172 may include an active component and/or a passive component. The active component may include various types of semiconductor chips, and the passive component may include various types of chip-type components such as chip capacitors or chip inductors. The passive component may also include an Integrated Passive Device (IPD). Each of the semiconductor chips may include an integrated circuit (IC) die in which hundreds to millions of components are integrated into a single chip. The integrated circuit may be, for example, a logic chip such as a central processor (e.g., a CPU), a graphics processor (e.g., a GPU), a field programmable gate array (FPGA), a digital signal processor, an encryption processor, a microprocessor, a microcontroller, an application processor (e.g., AP), an analog-to-digital converter, and an application-specific IC (ASIC), but is not limited thereto, and may also be a memory chip such as volatile memory (e.g., a DRAM), non-volatile memory (e.g., a ROM), flash memory and High Bandwidth Memory (HBM), or other types of chips such as a Power Management IC (PMIC). Additionally, the integrated circuit may have a form in which multiple functions are integrated into one chip, such as System on Chip (SoC).

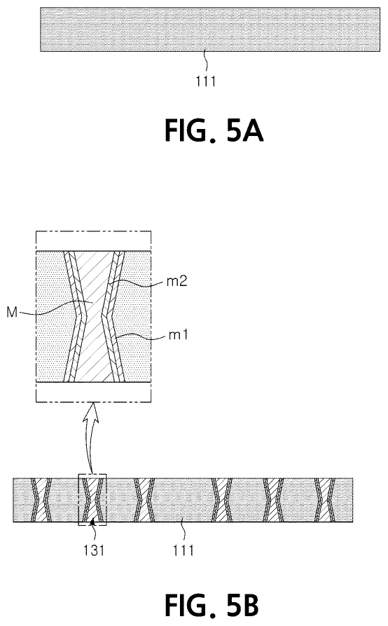

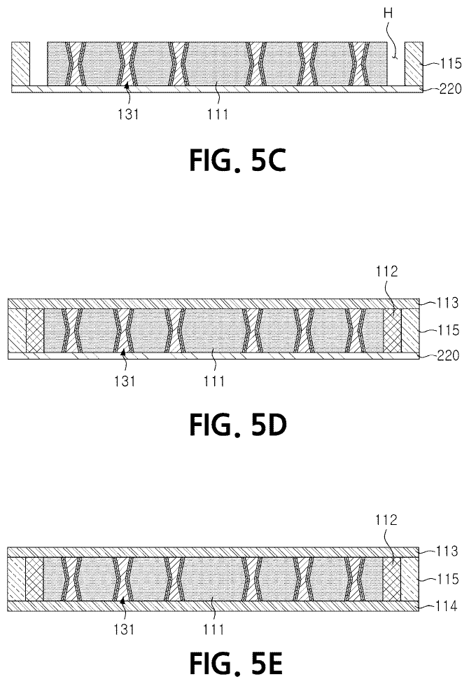

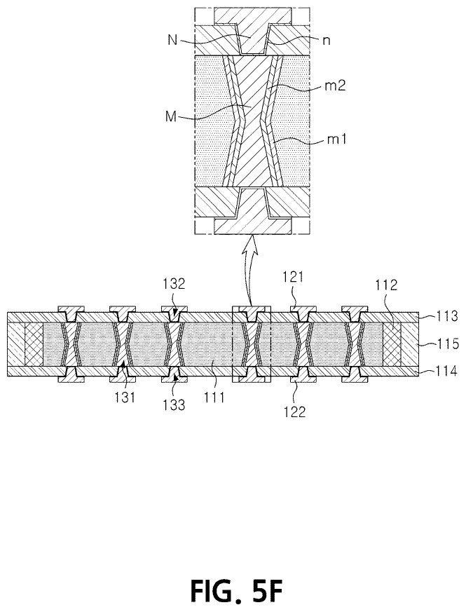

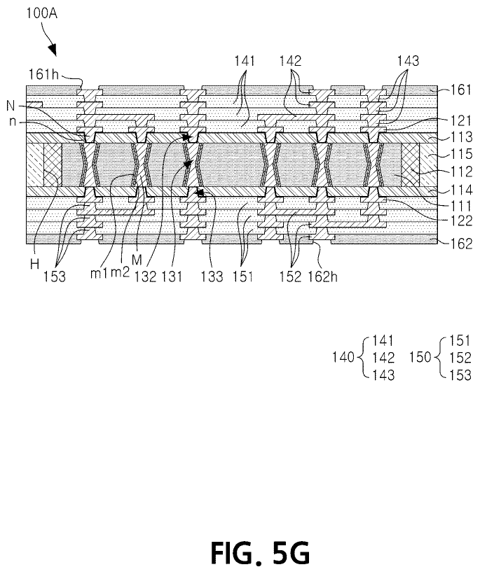

FIGS. 5A to 5G are process diagrams schematically illustrating an example of manufacturing a printed circuit board of FIG. 2.

Referring to FIG. 5A, a glass layer 111 may be prepared. The glass layer 111 may be in the form of a glass plate. Accordingly, the glass layer 111 may be easily applied to a large-area substrate. The glass layer 111 may have a substantially rectangular shape in a cross-section, and may have a substantially square or rectangular shape in a plane.

Referring to FIG. 5B, a through-via 131 penetrating through the glass layer 111 may be formed. For example, a through-hole may be formed in the glass layer 111 by various methods such as laser processing, mechanical processing, and chemical processing, first seed layers m1 and m2 may be formed on a wall surface of the through-hole, and a first metal layer M filling at least a portion of the through-hole may be formed on the first seed layers m1 and m2, thereby forming a through-via 131. The through-hole may be formed to penetrate through the glass layer 111 and have a substantially hourglass shape in a cross-section. The first seed layers m1 and m2 may be formed by sputtering with a material including titanium and a material including copper. The first metal layer M may be formed by electrolytic plating with the material including copper. Plating layers on an upper surface and a lower surface of the glass layer 111 may be removed by etching.

Referring to FIG. 5C, at least a portion of the glass layer 111 may be disposed within the through-hole H. For example, a tape 220 blocking a lower side of the through-portion H may be attached to a lower side of the frame 115, and then the glass layer 111 may be attached onto the tape 220 exposed from the through-portion H. The frame 115 may have a jig shape. The tape 220 may include polyimide (PI), or the like, but the material is not particularly limited thereto.

Referring to FIG. 5D, at least a portion of a space between the frame 115 and the glass layer 111 may be filled with a first insulating material 112. For example, the remaining space of the through-portion H may be filled with the first insulating material 112. Additionally, a second insulating material 113 including a different material from the first insulating material 112 may be formed on uppers side of each of the frame 115, the glass layer 111, and the first insulating material 112. If necessary, flattening may be performed.

Referring to FIG. 5E, the tape 220 may be removed, and a third insulating material 114 including a different material from the first insulating material 112 may be formed on lower sides of each of the frame 115, the glass layer 111, and the first insulating material 112. The second and third insulating materials 113 and 114 may include substantially the same material. If necessary, flattening may be performed.

Referring to FIG. 5F, a first connection via 132 which penetrates through the second insulating material 113 and is disposed on upper surfaces of the first connection via 132 and the second insulating material 113 connected to the upper surface of the through-via 131 and in which at least a portion thereof may form the first interconnection layer 121 connected to the first connection via 132 may be formed. Additionally, a second connection via 133 which penetrates the third insulating material 114 and is disposed on lower surfaces of the second connection via 133 and the third insulating material 114 connected to the lower surface of the through-via 131 and in which at least a portion thereof may form the second interconnection layer 122 connected to the second connection via 133 may be formed. For example, a first via hole penetrating through the second insulating material 113 and having a substantially tapered shape in which a width of an upper end thereof is greater than a width of a lower end thereof in the cross-section may be formed, a second seed layer n may be formed on a wall surface of the first via hole by electroless plating with a material including copper, and a second metal layer N filling at least a portion of the first via hole may be formed on the second seed layer n by electrolytic plating with a material including copper, thereby forming a first connection via 132. In substantially the same manner, a second via hole penetrating through the third insulating material 114 and having a substantially tapered shape in which a width of a lower end thereof is greater than a width of an upper end thereof in the cross-section may be formed, a third seed layer may be formed on the wall surface of the second via hole by electroless plating with a material including copper, and a third metal layer filling at least a portion of the second via hole may be formed on the third seed layer by electrolytic plating with a material including copper, thereby forming a second connection via 133. When forming the first and second connection vias 132 and 133, the first and second interconnection layers 121 and 122 may also be formed together.

Referring to FIG. 5G, the first and second build-up layers 140 and 150 may be formed on an upper side of the second insulating material 113 and a lower side of the third insulating material 114, respectively. For example, by utilizing a build-up process and a plating process, a plurality of first and second build-up insulating layers 141 and 151, a plurality of first second build-up interconnection layers 142 and 152, and a plurality of first and second build-up via layers 143 and 153 may be formed, thereby forming first and second build-up layers 140 and 150. Additionally, first and second solder resist layers 161 and 162 may be formed by a lamination process or a coating process. Additionally, a plurality of first and second openings 161h and 162h may be formed in the first and second solder resist layers 161 and 162 by laser processing or a photolithography process, respectively. If necessary, a plurality of first and second electrical connection metals may be formed, and the first and second electronic components may be mounted.

The printed circuit board 100A described above may be manufactured through a series of processes. Other details may be substantially the same as those described in the printed circuit board 100A according to the above-described example embodiment.

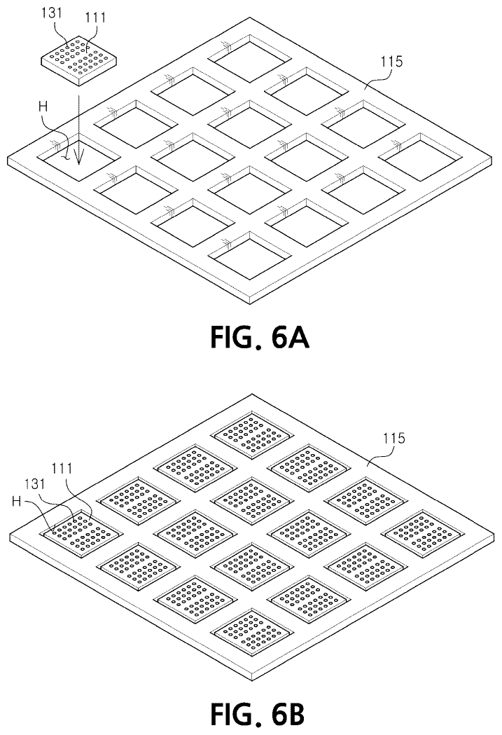

FIG. 6A and FIG. 6B are process diagrams schematically illustrating an example of disposing a plurality of glass layers in a frame having a plurality of through-portions.

Referring to the drawings, the frame 115 may have a plurality of through-portions H, and a plurality of glass layers 111 may be disposed in each of the plurality of through-portions H. Each of the plurality of glass layers 111 may have a through-via 131 formed through the manufacturing process of FIG. 5A to FIG. 5C described above, and may be disposed in each of the plurality of through-portions H using the tape described above. Then, the manufacturing process of FIG. 5D to FIG. 5G described above may be performed to manufacture a panel substrate including a plurality of printed circuit board 100A units. Then, the plurality of printed circuit board 100A units may be obtained by cutting a space of between the plurality of through-portions H. For example, the plurality of printed circuit board 100A units may be manufactured together in a process on a panel level, and may be separated individually by a singulation process. Accordingly, this may be advantageous for process warpage control, and productivity also be excellent.

Other details may be substantially the same as those described in the printed circuit board 100A and the manufacturing example thereof according to the above-described example.

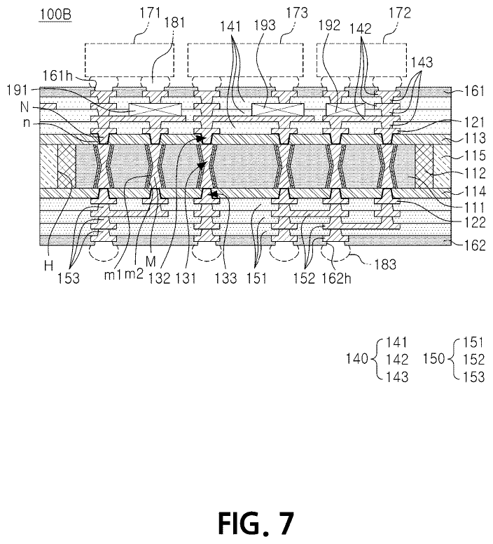

FIG. 7 is a cross-sectional view schematically illustrating another example of a printed circuit board.

Referring to FIG. 7, a printed circuit board 100B according to another example embodiment may further include a third electronic component 173 mounted on a first solder resist layer 161 through a plurality of first electrical connection metals 181, in the printed circuit board 100A according to the above-described example embodiment. Additionally, the printed circuit board 100B may further include first to third electronic components 191, 192 and 193 embedded in each of the plurality of first build-up insulating layers 141 and connected to at least a portion of at least one of the plurality of first build-up interconnection layers 142 through at least a portion of at least one of the plurality of first build-up via layers 143. For example, a printed circuit board 100B according to another example embodiment may be a board in which electronic components are embedded in a build-up region.

Hereinafter, components of another printed circuit board 100B will be described in more detail with reference to the drawings.

The third electronic component 173 may include an active component and/or a passive component. The active component may include various types of semiconductor chips, and the passive component may include various types of chip-type components such as chip capacitors or chip inductors. The passive component may also include an Integrated Passive Device (IPD). Each of the semiconductor chips may include an integrated circuit (IC) di in which hundreds to millions of components are integrated into a single chip. The integrated circuit may be, for example, a logic chip such as a central processor (e.g., a CPU), a graphics processor (e.g., a GPU), a field programmable gate array (FPGA), a digital signal processor, an encryption processor, a microprocessor, a microcontroller, an application processor (e.g., AP), an analog-to-digital converter, and an application-specific IC (ASIC), but is not limited thereto, and may also be a memory chip such as a volatile memory (e.g., a DRAM), a non-volatile memory (e.g., a ROM), a flash memory and a high bandwidth memory (HBM), or other types of chips such as a Power Management IC (PMIC). The third electronic component 173 may also may have a form in which multiple functions are integrated into one chip, such as System on Chip (SoC).

Each of the first to third electronic components 191, 192 and 193 may include an interconnect bridge, an active component, and/or a passive component. The interconnect bridge may transmit an electrical signal between at least two of the first to third electronic components 171, 172 and 173 through a high-density circuit therein. The interconnect bridge may be a silicon bridge, an organic bridge, or the like. The active component may include various types of semiconductor chips, and the passive component may include various types of chip-type components such as chip capacitors or chip inductors. The passive component may include an Integrated Passive Device (IPD). Each of the semiconductor chips may include an integrated circuit (IC) die in which hundreds to millions of components are integrated into a single chip. In this case, the integrated circuit may be, for example, a logic chip such as a central processor (e.g., a CPU), a graphics processor (e.g., a GPU), a field programmable gate array (FPGA), a digital signal processor, an encryption processor, a microprocessor, a microcontroller, an application processor (e.g., AP), an analog-to-digital converter, and an ASIC (application-specific IC), but is not limited thereto, and may be a memory chip such as a volatile memory (e.g., a DRAM), a non-volatile memory (e.g., a ROM), a flash memory and a High Bandwidth Memory (HBM), or other types of chips such as a Power Management IC (PMIC). Additionally, the first to third electronic components 191, 192 and 193 may also may have a form in which multiple functions are integrated into one chip, such as System on Chip (SoC).

Other details may be substantially the same as those described in the printed circuit board 100A according to the above-described example embodiment and the manufacturing example thereof.

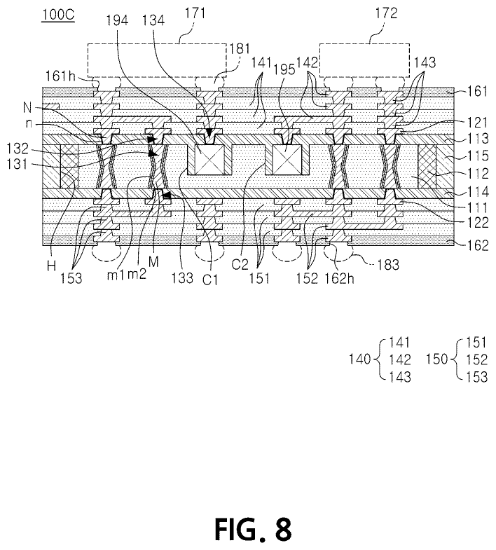

FIG. 8 is a cross-sectional view schematically illustrating another example of a printed circuit board.

Referring to FIG. 8, a printed circuit board 100C according to another example embodiment may further include fourth and fifth electronic components 194 and 195 embedded in the glass layer 111, in the printed circuit board 100A according to the above-described example embodiment. For example, the fourth and fifth electronic components 194 and 195 may be respectively disposed in cavities C1 and C2 formed in the glass layer 111 and covered with second insulating material 113, and may be respectively connected to at least a portion of the first interconnection layer 121 through third connection vias 134 penetrating through the second insulating material 113. The cavities C1 and C2 may be blind cavities penetrating a portion of the upper surface of the glass layer 111, but may also be through-cavities penetrating between the upper surface and the lower surface of the glass layer 111 as needed. For example, a printed circuit board 100C according to another example embodiment may be a board having electronic components embedded in a core region.

Hereinafter, components of another printed circuit board 100C will be described in more detail with reference to the drawings.

Each of the fourth and fifth electronic components 194 and 195 may include an interconnect bridge, an active component, and/or a passive component. The interconnect bridge may transmit an electrical signal between the first and second electronic components 171 and 172 through a high-density circuit therein. The interconnect bridge may be a silicon bridge, an organic bridge, or the like. The active component may include various types of semiconductor chips, and the passive component may include various types of chip-type components such as a chip capacitor or a chip inductor. The passive component may also include an Integrated Passive Device (IPD). Each of the semiconductor chips may include an integrated circuit (IC) die in which hundreds to millions of elements are integrated into a single chip. In this case, the integrated circuit may be, for example, a logic chip such as a central processor (e.g., a CPU), a graphics processor (e.g., GPU), a field programmable gate array (FPGA), a digital signal processor, an encryption processor, a microprocessor, a microcontroller, an application processor (e.g., AP), an analog-to-digital converter, and an application-specific IC (ASIC), but is not limited thereto, and may be a memory chip such as a volatile memory (e.g., a DRAM), a non-volatile memory (e.g., a ROM), a flash memory and a high bandwidth memory (HBM), or other types of chips such as a power management IC (PMIC). Additionally, the fourth and fifth electronic components 194 and 195 may have a form in which multiple functions are integrated into one chip, such as System on Chip (SoC).

The third connection via 134 may include a metal. The metal may include copper (Cu), aluminum (Al), silver (Ag), tin (Sn), gold (Au), nickel (Ni), lead (Pb), titanium (Ti), and/or alloys thereof. The third connection via 134 may include a filled VIA filling a via hole, but may also include a conformal VIA disposed along a wall surface of the via hole. The third connection via 134 may perform various functions depending on the design. For example, the third connection via 134 may include a ground via, a power via, and a signal via. The third connection via 134 may have a substantially tapered shape in which a width of an upper end thereof is greater than a width of a lower end thereof in the cross-section, but the present disclosure is not limited thereto. The third connection via 134 may include an electroless plating layer (or chemical copper) and an electrolytic plating layer (or electrolytic copper). The third connection via 134 may be provided in plural.

The technical features of the printed circuit board 100C according to another example embodiment may also be applied to the printed circuit board 100B according to the other example described above. Other details may be substantially the same as those described in the printed circuit board 100A according to the above-described example embodiment and the manufacturing example thereof, and the printed circuit board 100B according to the other example described above.

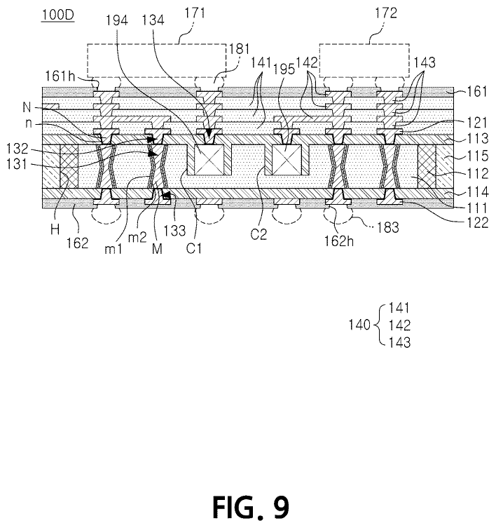

FIG. 9 is a cross-sectional view schematically illustrating another example of a printed circuit board.

Referring to FIG. 9, a printed circuit board 100D according to another example embodiment may be configured so that only a first build-up layer 140 including a plurality of first build-up insulating layers 141, a plurality of first build-up interconnection layers 142 and a plurality of first build-up via layers 143 is present, and a second build-up layer 150 including a plurality of second build-up insulating layers 151, a plurality of second build-up interconnection layers 152 and a plurality of second build-up via layers 153 may be omitted, in the printed circuit board 100A according to the above-described example embodiment. Additionally, the printed circuit board 100D may further include fourth and fifth electronic components 194 and 195 embedded in a glass layer 111. For example, the fourth and fifth electronic components 194 and 195 may be respectively disposed in cavities C1 and C2 formed in the glass layer 111 and may be covered with a second insulating material 113, and may be respectively connected to at least a portion of the first interconnection layer 121 through third connection vias 134 penetrating through the second insulating material 113. Each of the cavities C1 and C2 may be blind cavities penetrating through a portion of the glass layer 111 from the upper surface of the glass layer 111, but may also be through-cavities penetrating between the upper surface and the lower surface of the glass layer 111 if necessary. For example, a printed circuit board 100D according to another example embodiment may have an asymmetrical build-up structure, and electronic components may be embedded in the core region. The electronic component-embedded board having the asymmetrical build-up structure may be easily applied to an interposer board, or the like. Hereinafter, components of another printed circuit board 100D will be described in more detail with reference to the drawings.

The asymmetrical structure may be formed so that a build-up layer is formed only on an upper side thereof based on a core layer including the glass layer 111, the first to third insulating materials 112, 113 and 114, and the frame 115. However, the present disclosure is not limited thereto, and if necessary, the asymmetrical structure may be formed so that the build-up layer may be formed only on a lower side thereof based on the core layer including the glass layer 111, the first to third insulating materials 112, 113 and 114, and the frame 115. Alternatively, if necessary, the asymmetrical structure may be formed so that the build-up layer may be formed on both the upper side and the lower side thereof based on the core layer including the glass layer 111, the first to third insulating materials 112, 113 and 114, and the frame 115, but the number of layers thereof may be different.

Each of the fourth and fifth electronic components 194 and 195 may include an interconnect bridge, an active component, and/or a passive component. The interconnect bridge may transmit an electrical signal between the first and second electronic components 171 and 172 through a high-density circuit therein. The interconnect bridge may be a silicon bridge, an organic bridge, or the like. The active component may include various types of semiconductor chips, and the passive component may include various types of chip-type components, such as chip capacitors or chip inductors. The passive component may include an Integrated Passive Device (IPD). The semiconductor chip may include an integrated circuit (IC) die in which hundreds to millions of components are integrated into a single chip. In this case, the integrated circuit may be, for example, a logic chip such as a central processor (e.g., a CPU), a graphics processor (e.g., a GPU), a field programmable gate array (FPGA), a digital signal processor, an encryption processor, a microprocessor, a microcontroller, an application processor (e.g., AP), an analog-to-digital converter, and an application-specific IC (ASIC), but is not limited thereto, and may be a memory chip such as a volatile memory (e.g., a DRAM), a non-volatile memory (e.g., a ROM), a flash memory and a high bandwidth memory (HBM), or other types of chips such as a power management IC (PMIC). Additionally, the fourth and fifth electronic components 194 and 195 may have a form in which multiple functions are integrated into one chip, such as System on Chip (SoC).

The third connection via 134 may include metal. The metal may include copper (Cu), aluminum (Al), silver (Ag), tin (Sn), gold (Au), nickel (Ni), lead (Pb), titanium (Ti), and/or alloys thereof. The third connection via 134 may include a filled via filling a via hole, but may also include a conformal via disposed along a wall surface of the via hole. The third connection via 134 may perform various functions depending on the design. For example, the third connection via 134 may include a ground via, a power via, and a signal via. The third connection via 134 may have a substantially tapered shape in which a width of an upper end thereof is greater than a width of a lower end thereof in the cross-section, but the present disclosure is not limited thereto. The third connection via 134 may include an electroless plating layer (or chemical copper) and an electrolytic plating layer (or electrolytic copper). The third connection via 134 may be provided in plural.

The technical features of the printed circuit board 100D according to another example embodiment may also be applied to the printed circuit board 100B according to the above-described other example embodiment, and the printed circuit board 100C according to another example embodiment described above, respectively. Other details may be substantially the same as described in the printed circuit board 100A according to the above-described one example embodiment and the manufacturing example thereof, the printed circuit board 100B according to the above-described other example, and the printed circuit board 100C according to another example embodiment described above.

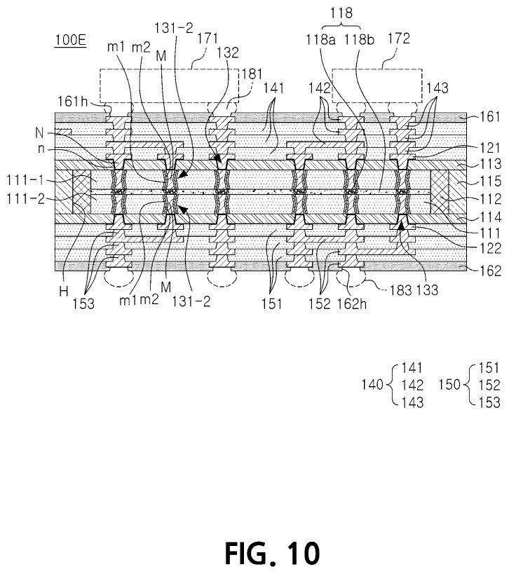

FIG. 10 is a cross-sectional view schematically illustrating another example of a printed circuit board.

Referring to FIG. 10, a printed circuit board 100E according to another example embodiment may be configured so that the glass layer 111 may include first and second glass layers 111-1 and 111-2 spaced apart from each other in a thickness direction, in the printed circuit board 100A according to the above-described one example embodiment. Additionally, the through-via 131 may include a first through-via 131-1 penetrating through the first glass layer 111-1 and a second through-via 131-2 penetrating through the second glass layer 111-2. Additionally, a conductive film 118 including conductive particles 118a electrically connecting the first and second through-vias 131-1 and 131-2 may be disposed between the first and second glass layers 111-1 and 111-2. For example, such a structure may be introduced when a thicker core layer is required.

Hereinafter, components of another printed circuit board 100E will be described in more detail with reference to the drawings.

The conductive film 118 may include conductive particles 118a and an insulating resin 118b. The conductive particles 118a may be metal particles, and may include, for example, particles of gold (Au), silver (Ag), nickel (Ni), copper (Cu), or alloys thereof. If necessary, the metal particles may be polymer particles having a metal coating applied to surfaces thereof. The insulating resin 118b may stably fix the conductive particles 118a and may provide necessary mechanical strength and insulating properties. The insulating resin 118b may include a thermosetting resin such as an epoxy resin or polyimide, and a thermoplastic resin such as polyethylene terephthalate or polycarbonate. The conductive film 118 may include an anisotropic conductive film (ACF) or an anisotropic conductive paste (ACP), but the present disclosure is not limited thereto. Such films may provide properties such as adhesion, mechanical strength, and thermal stability in addition to electrical conductivity.

The technical features of the printed circuit board 100E according to another example embodiment may also be applied to the printed circuit board 100B according to the above-described other example embodiment, the printed circuit board 100C according to another example embodiment described above, and the printed circuit board 100D according to the above-described other example embodiment. Other details may be substantially the same as described in the printed circuit board 100A according to the above-described example embodiment and the manufacturing example thereof, the printed circuit board 100B according to another example embodiment described above, the printed circuit board 100C according to another example embodiment described above, and the printed circuit board 100D according to another example embodiment described above.

In the present disclosure, a thickness, a width, a length, a pitch, a depth, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. When the value is not constant, the value may be determined as an average value of values measured at five arbitrary points. A width of an upper end and/or a lower end of a via may be measured on a cross-section that has been cut along a central axis of the via in a thickness direction of the board. A depth of the via may be measured as a distance from an upper end to a lower end of the via on a cross-section that has been cut along the central axis of the via in the thickness direction of the board.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist.

In the present disclosure, determination may be performed by including process errors, positional deviations, errors at the time of measurement, which may occur in a manufacturing process. For example, the meaning that a line width, a gap, a thickness, a height, and the like, are substantially the same may include cases in which they are numerically completely the same, as well as those having approximately similar values. Furthermore, substantially having a certain shape may include not only the case of having such a shape completely but also the case of having such a shape approximately. Furthermore, substantially coplanar may include not only the case of being completely coplanar but also the case of being approximately coplanar.

Furthermore, substantially the same material may mean not only the case of being the completely same material but also the case of including the same type of material. Accordingly, the composition of the material may be substantially the same, but the specific composition ratio thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. In addition, a side portion and a side surface are used to mean directions perpendicular to an upper surface and a lower surface. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Additionally, the term electrically connected includes both physically connected and not physically connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a frame having a through-portion;
a glass layer at least partially disposed within the through-portion;
a first insulating material filling at least a portion of a space between the frame and the glass layer;
a second insulating material disposed above the frame and the glass layer relative to a thickness thereof; and
a third insulating material disposed below the frame and the glass layer relative to the thickness thereof,
wherein the first insulating material includes a material different from the second and third insulating materials.

2. The printed circuit board according to claim 1, wherein the second insulating material is in contact with at least a portion of an upper surface of each of the frame, the glass layer, and the first insulating material, and
the third insulating material is in contact with at least a portion of a lower surface of each of the frame, the glass layer, and the first insulating material.

3. The printed circuit board according to claim 2, wherein the first to third insulating materials form respective insulating layer having distinct boundaries therebetween,
the upper surface of the first insulating material is substantially coplanar with the upper surface of the glass layer, and
the lower surface of the first insulating material is substantially coplanar with the lower surface of the glass layer.

4. The printed circuit board according to claim 1, wherein the first insulating material includes a first insulating resin and a first inorganic filler,
the second insulating material includes a second insulating resin, a second inorganic filler, and a first glass fiber, and
the third insulating material includes a third insulating resin, a third inorganic filler, and a second glass fiber.

5. The printed circuit board according to claim 4, wherein the first insulating material does not include the glass fiber.

6. The printed circuit board according to claim 4, wherein in a given cut cross-section, an area ratio of the inorganic filler included in the first insulating material is smaller than an area ratio of the inorganic filler included in the second insulating material and an area ratio of the inorganic filler included in the third insulating material, respectively.

7. The printed circuit board according to claim 1, wherein the through-portion penetrates between an upper surface and a lower surface of the frame, and
the frame includes a copper-clad laminate or an unclad copper-clad laminate.

8. The printed circuit board according to claim 1, wherein each of a coefficient of thermal expansion of the second insulating material and a coefficient of thermal expansion of the third insulating material is smaller than a coefficient of thermal expansion of the glass layer.

9. The printed circuit board according to claim 8, wherein each of a coefficient of thermal expansion of the frame and a coefficient of thermal expansion of the first insulating material is greater than the coefficient of thermal expansion of the glass layer.

10. The printed circuit board according to claim 1, further comprising:
a through-via penetrating through the glass layer;
a first connection via penetrating through the second insulating material and connected to an upper surface of the through-via;
a second connection via penetrating through the third insulating material and connected to a lower surface of the through-via; and
a first interconnection layer disposed on an upper surface of the second insulating material, wherein at least a portion thereof is connected to the first connection via; and
a second interconnection layer disposed on a lower surface of the third insulating material, wherein at least a portion thereof is connected to the second connection via.

11. The printed circuit board according to claim 10, wherein the through-via has a substantially hourglass shape in a cross-section,
the first connection via has a substantially tapered shape in the cross-section in which a width of an upper portion thereof is greater than a width of a lower portion thereof, and
the second connection via has a substantially tapered shape in the cross-section in which a width of a lower portion thereof is greater than a width of an upper portion thereof.

12. The printed circuit board according to claim 11, wherein the glass layer has a through-hole,
the through-via includes a first seed layer disposed on a wall surface of the through-hole and a first metal layer disposed on the first seed layer and filling at least a portion of the through-hole,
the first seed layer includes a first layer including sputtered titanium and a second layer disposed on the first layer and including sputtered copper, and
the first metal layer includes electrolytic copper.

13. The printed circuit board according to claim 12, wherein the second insulating material has a first via hole exposing the upper surface of the through-via,
the third insulating material has a second via hole exposing the lower surface of the through-via,
the first connection via includes a second seed layer disposed on a wall surface of the first via hole and the exposed upper surface of the through-via, and a second metal layer disposed on the second seed layer and filling at least a portion of the first via hole,
the second connection via includes a third seed layer disposed on a wall surface of the second via hole and the exposed lower surface of the through-via, and a third metal layer disposed on the third seed layer and filling at least a portion of the second via hole, and
each of the second and third seed layers includes chemical copper, and
each of the second and third metal layers includes electrolytic copper.

14. The printed circuit board according to claim 10, further comprising:
a first electronic component embedded in the glass layer; and
a third connection via penetrating through the second insulating material and connecting the first electronic component to at least another portion of the first interconnection layer,
wherein the first electronic component includes at least one of an interconnect bridge, an active component, and a passive component.

15. The printed circuit board according to claim 10, wherein the glass layer includes first and second glass layers spaced apart from each other in a thickness direction,
the through-via includes a first through-via penetrating through the first glass layer and a second through-via penetrating through the second glass layer, and
a conductive film including conductive particles electrically connecting the first and second through-vias is disposed between the first and second glass layers.

16. The printed circuit board according to claim 10, further comprising:
a plurality of first build-up insulating layers stacked on the upper surface of the second insulating material;
a plurality of first build-up interconnection layers respectively disposed on upper surfaces of the plurality of first build-up insulating layers or within the plurality of first build-up insulating layers; and
a plurality of first build-up via layers respectively disposed within the plurality of first build-up insulating layers.

17. The printed circuit board according to claim 16, further comprising:
a second electronic component embedded within the plurality of first build-up insulating layers and connected to at least a portion of at least one of the plurality of first build-up interconnection layers via at least a portion of at least one of the plurality of first build-up via layers;
wherein the second electronic component includes at least one of an interconnect bridge, an active component, and a passive component.

18. The printed circuit board according to claim 16, further comprising:
a first solder resist layer disposed on an upper surface of a first build-up insulating layer disposed on an uppermost side, among the plurality of first build-up insulating layers, and having a plurality of first openings respectively exposing at least a portion of the first build-up interconnection layer disposed on an uppermost side, among the plurality of first build-up interconnection layers;
a second solder resist layer disposed on a lower surface of the third insulating material, and having a plurality of second openings respectively exposing at least a portion of the second interconnection layer;
a plurality of first electrical connection metals respectively disposed on the plurality of first openings, and respectively connected to at least the exposed portion of the first build-up interconnection layer disposed on the uppermost side;
an electronic component mounted on an upper surface of the first solder resist layer, and connected to the plurality of first electrical connection metals; and
a plurality of second electrical connection metals respectively disposed on the plurality of second openings, and respectively connected to at least the exposed portion of the second interconnection layer,
wherein the electronic component includes one or more of an active component and a passive component.

19. The printed circuit board according to claim 16, further comprising:
a plurality of second build-up insulating layers stacked on the lower surface of the third insulating material;
a plurality of second build-up interconnection layers respectively disposed on lower surfaces of the plurality of second build-up insulating layers or within the plurality of second build-up insulating layers; and
a plurality of second build-up via layers respectively disposed within the plurality of second build-up insulating layers.

20. The printed circuit board according to claim 19, further comprising:
a first solder resist layer disposed on an upper surface of a first build-up insulating layer disposed on an uppermost side, among the plurality of first build-up insulating layers, and having a plurality of first openings respectively exposing at least a portion of a first build-up interconnection layer disposed on an uppermost side, among the plurality of first build-up interconnection layers;
a second solder resist layer disposed on a lower surface of a second build-up insulating layer, among the plurality of second build-up interconnection layers, and having a plurality of second openings respectively exposing at least a portion of a second build-up interconnection layer disposed on a lowermost side, among the plurality of second build-up insulating layers;
a plurality of first electrical connection metals disposed on the plurality of first openings, and respectively connected to at least the exposed portion of the first build-up interconnection layer disposed on the uppermost side;
an electronic component mounted on an upper surface of the first solder resist layer, and connected to the plurality of first electrical connection metals; and
a plurality of second electrical connection metals disposed on the plurality of second openings, and respectively connected to at least the exposed portion of the second build-up interconnection layer disposed on the lowermost side,
wherein the electronic component includes one or more of an active component and a passive component.

21. A printed circuit board, comprising:
a glass layer;
a frame spaced apart from the glass layer and surrounding a side surface of the glass layer;
a first insulating material filling at least a portion of a space between the glass layer and the frame;
a second insulating material covering at least a portion of an upper surface of each of the glass layer, the frame, and the first insulating material; and
a third insulating material covering at least a portion of a lower surface of each of the glass layer, the frame, and the first insulating material,
wherein the first and second insulating materials have boundaries physically distinct from each other, and
the first and third insulating materials have boundaries physically distinct from each other.

22. The printed circuit board according to claim 21, wherein each of a coefficient of thermal expansion of the frame and a coefficient of thermal expansion of the first insulating material is greater than a coefficient of thermal expansion of the glass layer, and
the coefficient of thermal expansion of the glass layer is greater than each of a coefficient of thermal expansion of the second insulating material and a coefficient of thermal expansion of the third insulating material.

23. The printed circuit board according to claim 21, further comprising:
a through-via penetrating through the glass layer;
a first connection via penetrating through the second insulating material and connected to an upper surface of the through-via;
a second connection via penetrating through the third insulating material and connected to a lower surface of the through-via;
a first interconnection pattern disposed above the second insulating material in cross-section and connected to the first connection via; and
a second interconnection pattern disposed below the third insulating material in cross-section and connected to the second connection via,
wherein the through-via has a substantially hourglass shape in a cross-section,
the first and second connection vias have substantially tapered shapes in opposite directions in the cross-section,
the through-via includes a first layer including sputtered titanium as a seed layer and a second layer including sputtered copper, and
each of the first and second connection vias includes chemical copper as a seed layer.

24. The printed circuit board according to claim 23, further comprising:
a build-up layer disposed above the second insulating material, below the third insulating material, or above the second insulating material and below the third insulating material,
wherein the build-up layer includes one or more build-up insulating layers, one or more build-up interconnection layers respectively disposed on or within the one or more build-up insulating layers, and one or more build-up via layers respectively disposed within the one or more build-up insulating layers.

25. A method for manufacturing a printed circuit board, comprising:
preparing a frame having a through-portion;
disposing at least a portion of a glass layer within the through-portion;
filling at least a portion of a space between the frame and the glass layer with a first insulating material;
forming a second insulating material including a material different from the first insulating material, above each of the frame, the glass layer and the first insulating material in cross-section; and
forming a third insulating material including a material different from the first insulating material, below each of the frame, the glass layer and the first insulating material in cross-section.

26. The method for manufacturing a printed circuit board according to claim 25, wherein each of a coefficient of thermal expansion of the frame and a coefficient of thermal expansion of the first insulating material is greater than a coefficient of thermal expansion of the glass layer, and
the coefficient of thermal expansion of the glass layer is greater than each of a coefficient of thermal expansion of the second insulating material and a coefficient of thermal expansion of the third insulating material.

27. The method for manufacturing a printed circuit board according to claim 25, further comprising,
before the disposing at least a portion of a glass layer within the through-portion,
forming a through-via penetrating through the glass layer,
wherein the forming a through-via includes:
forming a through-hole penetrating through the glass layer and having a substantially hourglass shape in a cross-section,
forming a first seed layer by sputtering a material including titanium and a material including copper on a wall surface of the through-hole, and
forming a first metal layer filling at least a portion of the through-hole by performing electrolytic plating on a material including copper on the first seed layer.

28. The method for manufacturing a printed circuit board according to claim 27, further comprising,
after the forming the second and third insulating materials,
forming a first connection via penetrating through the second insulating material and connected to an upper surface of the through-via, and a first interconnection layer which is disposed on an upper surface of the second insulating material and in which at least a portion thereof is connected to the first connection via;
forming a second connection via penetrating through the third insulating material and connected to a lower surface of the through-via, and a second interconnection layer which is disposed on a lower surface of the third insulating material and in which at least a portion thereof is connected to the second connection via,
wherein the forming a first connection via includes:
forming a first via hole penetrating through the second insulating material and having a substantially tapered shape in which a width of an upper portion thereof is greater than that of a lower portion thereof in a cross-section;
forming a second seed layer on a wall surface of the first via hole by electroless plating with a material including copper, and
forming a second metal layer filling at least a portion of the first via hole by electrolytic plating with the material including copper on the second seed layer, and
the forming a second connection via includes:
forming a second via hole penetrating through the third insulating material and having a substantially tapered shape in which a width of a lower portion thereof is greater than that of an upper portion thereof in a cross-section;
forming a third seed layer on a wall surface of the second via hole by electroless plating with the material including copper;
forming a third metal layer filling at least a portion of the third via hole by electrolytic plating with the material including copper on the third seed layer.

29. The method for manufacturing a printed circuit board according to claim 28, further comprising,
after the forming the first and second connection vias and the first and second interconnection layers,
forming a build-up layer above the second insulating material and below the third insulating material, or above the second insulating material and below the third insulating material,
wherein the method includes:
forming the build-up layer;
forming one or more build-up insulating layers,
forming one or more build-up interconnection layers respectively disposed on or within the one or more build-up insulating layers; and
forming one or more build-up via layers respectively disposed within the one or more build-up insulating layers.

30. The method for manufacturing a printed circuit board according to claim 29, wherein in the preparing the frame, the through-portion are formed in plural, and
in the disposing the glass layer, at least a portion of the glass layer is disposed in each of the plurality of through-portions,
wherein the method includes,
after the forming the build-up layer,
forming a plurality of unit substrates by cutting a space between the plurality of through-portions.

31. A printed circuit board, comprising:
a frame having a through-portion;
a glass layer at least partially disposed within the through-portion, side-walls of the glass layer being spaced apart from inner side-walls of the through-portion of the frame;
a first insulating material filling at least a portion of a space between the frame and the glass layer; and
a second insulating material disposed to be contacting a surface of the frame and the glass layer,
wherein a coefficient of thermal expansion of the first insulating material is greater than a coefficient of thermal expansion of the glass layer and a coefficient of thermal expansion of the second insulating material is smaller than the coefficient of thermal expansion of the glass layer.
